(19) United States
(12) Patent Application Publication
(10) Pub. No.: US 2009/0079439 A1
(43) Pub. Date: Mar. 26, 2009

(54) EFUSE SYSTEM AND TESTING METHOD THEREOF

(75) Inventor: Chien-Li Kuo, Hsinchu (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/858,638

(22) Filed: Sep. 20, 2007

(51) Int. Cl. G01R 31/07

(52) U.S. Cl. 324/550

(57) ABSTRACT

An eFuse system and a method for testing the eFuse system are provided. The eFuse system includes an eFuse, a sensing circuit, and an offset resistor. The sensing circuit has a trigger point resistance and is coupled to a first end of the eFuse for sensing the resistance of the eFuse, wherein the resistance depends on whether the eFuse is blown or not. Accordingly, the sensing circuit outputs a first signal if the sensed resistance is greater than the trigger point resistance and outputs a second signal if the sensed resistance is less than the trigger point resistance. The offset resistor is coupled to a second end of the eFuse for compensating a shift on the trigger point resistance of the sensing circuit due to temperature change.

### BACKGROUND OF THE INVENTION

1. Field of the Invention

The present invention generally relates to a sensing circuit and a testing method thereof, in particular, to an eFuse system and a testing method thereof.

2. Description of Related Art

Along with the advance of chipset design, an innovated technique, electric fuse (eFuse), is published by International Business Machines (IBM) Corporation. The eFuse technique combines contemporary algorithms and micro electric fuse technique, such that through the eFuse technique, wafers can dynamically monitor, adjust, and repair themselves when a demand or a failure occurs in the system. Accordingly, using eFuse technique to produce wafers can enhance performance and evade failure due to unexpected demand.

In the eFuse technique, each wafer is disposed with a plurality of micro electronic fuses. To combine the micro electronic fuses with specific software, internal lines in the wafer can be changed automatically, so as to resolve problems happened in the wafer or enhance effectiveness of the wafer. Because the fuses is disposed inside the wafer, no additional cost is added to the production and the current flowed in the wafer can be controlled. Accordingly, the performance and the energy consumption of the wafer can be managed efficiently. For example, when the flow of the current gets too fast, the fuses can be used for adjusting the voltage of the wafer, so as to compensate some wafer defects.

On the other hand, if part of the wafer, for example, the storage part, works abnormal, the fuse can close the function of damaged wafer to ensure the other functions remain unaffected. Moreover, the eFuse can be used for reprogram the wafer according to user's demand, so as to enhance performance and stability of their processor products. With the eFuse technique, wafer manufacturer may modify the wafers with high flexibility and therefore the applied range can be expended.

FIG. 1 is a schematic diagram illustrating a conventional eFuse system. Referring to FIG. 1, the eFuse system includes an eFuse 110, a sensing circuit 120, a switch 130, and a blowing pad 140. The eFuse 110 is disposed between the sensing circuit 120 and the blowing pad 140, and has a program state and a non-program state. In the program state, the eFuse 110 has lower resistance while in the non-program state, it has higher resistance. The eFuse 110 can be blown by conducting a programming current on the blowing pad 140. On that time, the state of the eFuse 110 is transferred from the non-program state to the program state, during which the resistance of the eFuse 110 is reduced.

The sensing circuit 120 is used for sensing the resistance of the eFuse 110, and determining whether the sensed resistance is greater or less than a trigger point resistance, so as to output a signal with a higher voltage or a lower voltage. The switch 130 is disposed between the sensing circuit 120 and a ground voltage (Vss). The switch 130 receives a control signal Vg and accordingly activates the sensing circuit 120 to sense the resistance of the eFuse 110 and output the signal.

From the above, the eFuse can be easily programmed and used to remove defects occurred in the wafer or enhance effectiveness of the wafer. However, the difference of the resistances between the eFuses in the program state and non-program state is quite close and the eFuse element in the sensing circuit of the eFuse system is temperature dependent, such that if a user blows the eFuse at room temperature but tests it at higher temperature, some marginal passed bit will fail.

### SUMMARY OF THE INVENTION

Accordingly, the present invention is directed to an eFuse system, in which an offset resistor is coupled to an eFuse of the eFuse system for compensating the shift on the trigger point resistance due to temperature change.

The present invention is directed to a method for testing an eFuse system. In the method, simulations are performed on a plurality of eFuse systems under a plurality of “circumstances” to find an appropriate value of an offset resistance to be disposed to the eFuse system, so as to prevent marginal passed bit failure.

The present invention provides an eFuse system, which comprises an eFuse, a sensing circuit, and an offset resistor. The resistance of the eFuse depends on whether the eFuse is blown or not. The sensing circuit has a trigger point resistance and is coupled to a first end of the eFuse for sensing the resistance of the eFuse. The sensing circuit outputs a first signal if the sensed resistance is greater than the trigger point resistance and outputs a second signal if the sensed resistance is less than the trigger point resistance. The offset resistor is coupled to a second end of the eFuse for compensating a shift on the trigger point resistance of the sensing circuit due to temperature change.

According to an embodiment of the present invention, the eFuse system further comprises a first switch, which is disposed between the sensing circuit and a ground reference voltage. The first switch is used for enabling or disabling the sensing circuit to sense the resistance of the eFuse and output the signal accordingly.

According to an embodiment of the present invention, the eFuse system further comprises a power supply and a second switch. The power supply is capable of supplying a programming current. The second switch is disposed between the power supply and the eFuse for connecting or disconnecting the power supply to the eFuse and conducts the programming current to the eFuse for blowing the eFuse.

According to an embodiment of the present invention, the eFuse system further comprises a blowing pad, which is coupled to the second end of the eFuse and the second switch for transferring the programming current to the eFuse.

According to an embodiment of the present invention, the eFuse system further comprises a sensing reference pad and a testing circuit. The sensing reference pad is coupled to a second end of the offset resistor. The testing circuit is coupled to the sensing reference pad for supplying a testing signal to the offset resistor for testing the eFuse system. 6. The offset resistor, the sensing reference pad, and the testing circuit may be integrated on a board.

According to an embodiment of the present invention, the temperature ranges from −40 centigrade to 125 centigrade.

According to an embodiment of the present invention, the offset resistor comprises a poly resistor or a diffuse resistor and serially or parallelly connected with the eFuse of the eFuse system.

The present invention provides a method for testing an eFuse system. In the present method, simulations are performed on the eFuse system to detect a first trigger point resistance of a sensing circuit in the eFuse system at a first temperature and a second trigger point resistance of the sensing circuit at a second temperature. A shift between the two trigger point resistances is then calculated. An offset resistor is disposed to the eFuse system to compensate for the shift on the trigger point resistance of the sensing circuit.

According to an embodiment of the present invention, in the step of performing simulations on the eFuse system, simulations are further performed on a plurality of eFuse systems composed of different device components to detect a plurality of first trigger point resistances of the sensing circuits in the eFuse systems at the first temperature and a plurality of second trigger point resistance of the sensing circuits at the second temperature.

According to an embodiment of the present invention, in the step of performing simulations on the eFuse system, simulations are further performed on the eFuse system supplied with different voltages to detect a plurality of first trigger point resistances of the sensing circuits in the eFuse systems at the first temperature and a plurality of second trigger point resistance of the sensing circuits at the second temperature.

According to an embodiment of the present invention, the shift between the first trigger point resistance and the second trigger point resistance of the sensing circuit in each eFuse system is calculated and the offset resistor is disposed to the eFuse system to compensate for the shift on the trigger point resistances of the sensing circuit in the eFuse system.

According to an embodiment of the present invention, the offset resistor to be disposed is selected according to the calculated shift, so as to make the difference of the trigger point resistances of the sensing circuit before and after the compensation is larger than or equal to the shift.

According to an embodiment of the present invention, the eFuse system is programmed at the first temperature and tested at the second temperature. The first temperature is about 25 centigrade while the second temperature is about 90 centigrade.

In the present invention, simulations are performed on a plurality of eFuse systems composed of different device components or supplied with different voltages at a plurality of temperatures. An offset resistance is then selected accordingly to the result of those simulations and disposed to the eFuse system, such that the influence of temperature can be reduced effectively and the defects of marginal passed bit failure can be prevented.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a conventional eFuse system.

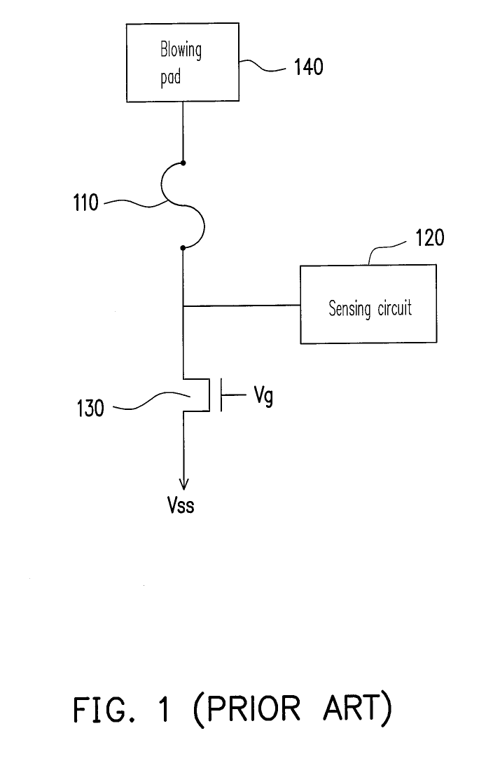

FIG. 2 is a block diagram illustrating an eFuse system according to an embodiment of the present invention.

FIG. 3 is a graph illustrating an eFuse system time split RF distribution according to an embodiment of the present invention.

FIG. 4 is a flowchart illustrating the method for testing an eFuse system according to one embodiment of the present invention.

FIG. 5 is a flowchart illustrating the method for testing an eFuse system according to one embodiment of the present invention.

FIG. 6 is a table illustrating the trigger point resistance detected in the simulations according to one embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In general, an eFuse system is programmed at room temperature (25 centigrade, for example) and tested at high temperature (90 centigrade, for example). However, the trigger point resistance of the sensing circuit in the eFuse system is temperature sensitive, such that the trigger point resistance usually increases whenever the eFuse system is tested. In order to eliminate the influence of temperature, the criteria for pass determination has to be raised, in which to dispose an offset resistor to the eFuse system is a way to accomplish the objective. Therefore, the present invention provides an eFuse system and a method for testing the eFuse system according to the foregoing concept. For a better understanding of the present invention, reference will now be made in detail to the present preferred embodiments of the invention, examples of which are illustrated in the accompanying drawings.

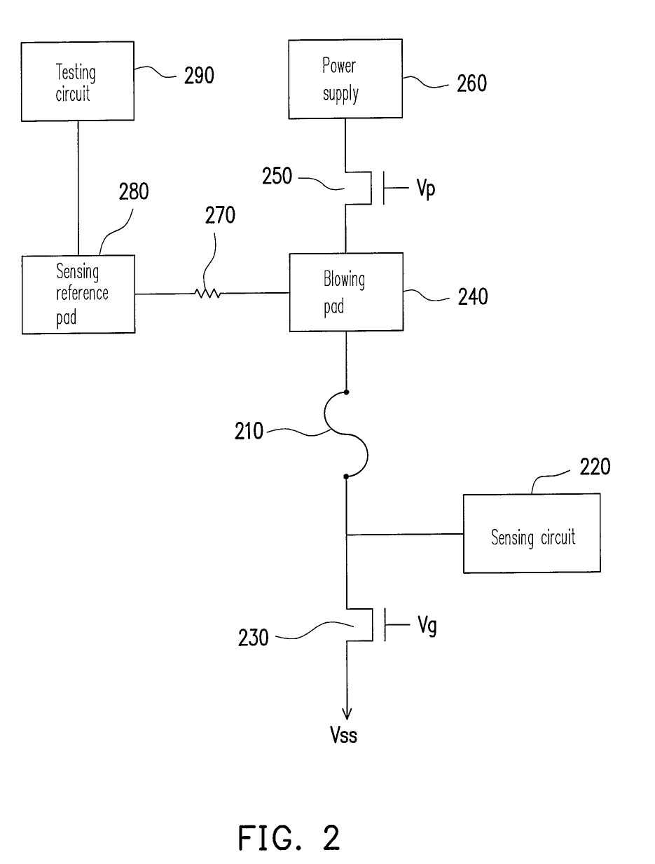

FIG. 2 is a block diagram illustrating an eFuse system according to an embodiment of the present invention. Referring to FIG. 2, the eFuse system includes an eFuse 210, a sensing circuit 220, a switch 230, a blowing pad 240, a switch 250, a power supply 260, an offset resistor 270, a sensing reference pad 280, and a testing circuit 290. The detail description and function about each of the above components are listed below, respectively.

As shown in FIG. 2, one end of the eFuse 210 is coupled to the sensing circuit 220 and switch 230, and the other end of the eFuse 210 is coupled to the blowing pad 240. The eFuse 210 has a program state and a non-program state. In the program state, the eFuse 210 has lower resistance while in the non-program state, it has higher resistance. The switch 250 receives a control signal Vs and conducts the programming current provided by the power supply 260 to the blowing pad 240 according to the control signal Vs. The eFuse 110 is then blown by the programming current supplied by the blowing pad 140 and the resistance of the eFuse 110 is reduced after the programming process.

The sensing circuit 220 is coupled to the eFuse 210 for sensing the state (program or non-program) of the eFuse 210, and outputting a signal according to the resistance of the eFuse 210. The sensing circuit 210 has a trigger point resistance, which is used as the criteria for determining which signal to be outputted. In detail, the sensing circuit 210 outputs a first signal if the sensed resistance is greater than a trigger point resistance and outputs a second signal if the sensed resistance is less than the trigger point resistance.

The switch 230 is disposed between the sensing circuit 220 and a ground reference voltage Vss. The gate of the switch 230 receives a control signal Vg so as to enable or disable the sensing circuit 220 to sense the resistance of the eFuse and output the signal accordingly. The switch 230 can be a complementary metal-oxide semiconductor (CMOS) transistor, but not limited to it.

The offset resistor 270 is connected to the eFuse 210 through the blowing pad 240 and used for compensating the shift on the trigger point resistance due to temperature change. The offset resistor 270 may be a poly resistor or a diffuse resistor, but not limited to them.

The sensing reference pad 280 is coupled to a second end of the offset resistor 270 and the testing circuit 290 is coupled to the sensing reference pad 280 for supplying a testing signal to the offset resistor 270 for testing the eFuse system.

In one embodiment, the offset resistor 270, the sensing reference pad 280, and the testing circuit 290 may be integrated on a separate board. Through this manner, the eFuse system can be programmed through conducting the programming current at the room temperature. However, when there is a need to test the eFuse system at the high temperature, the board with the offset resistor is connected to the blowing pad to compensate the trigger point resistance due to temperature change. Accordingly, the flexibility for testing is enhanced and the cost for testing is also reduced.

It is noted that the foresaid temperature change ranges from −40 centigrade to 125 centigrade and the shift on the trigger point resistance occurs since the eFuse system is usually programmed at a room temperature (about 25 centigrade) and tested at a higher temperature (about 90 centigrade). However, with the additionally disposed offset resistor 270, the criteria for pass determination is raised, such that the influence of temperature can be minimized.

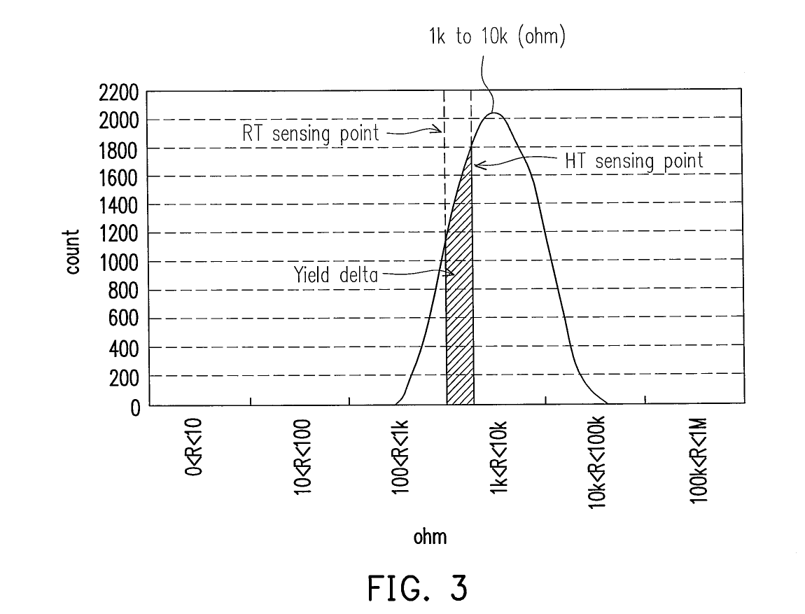

For example, FIG. 3 is a graph illustrating an eFuse system time split RF distribution according to an embodiment of the present invention. Referring to FIG. 3, the x-coordinate indicates a trigger point resistance of a sensing circuit in the eFuse system, and the y-coordinate indicates the count of pass bits, that is, the times that the sensed resistance of the eFuse is determined greater than the trigger point resistance. At room temperature (RT), the sensing point is at a lower level and the count of pass bits can be found on the curve. However, at high temperature (HT), the sensing point is at a higher level and some marginal passed bits fails. The amount of these failed marginal passed bits is indicated by the yield delta. Based on forgoing description, if the criteria for determining passed bit can be raised to the HT sensing point, the influence from the temperature should be able to be minimized. Therefore, in the present invention, an offset resistor is disposed to the eFuse system to achieve this goal. An embodiment illustrating the method for testing the eFuse system is further provided below.

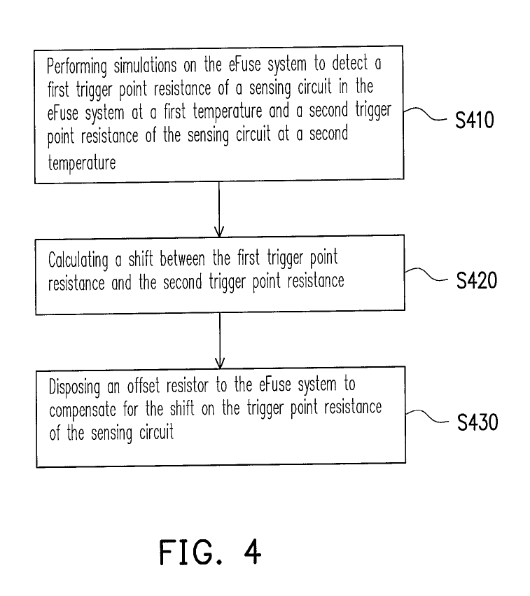

FIG. 4 is a flowchart illustrating the method for testing an eFuse system according to one embodiment of the present invention. Referring to FIG. 4, the present embodiment is applied to the aforesaid eFuse system and used for determining the resistance of the offset resistor to be disposed to the eFuse system, the detail steps for testing the eFuse system are described below.

First, simulations are performed on the eFuse system, so as to detect a first trigger point resistance of a sensing circuit in the eFuse system at a first temperature and a second trigger point resistance of the sensing circuit at a second temperature (S410). Then, a shift between the first trigger point resistance and the second trigger point resistance is calculated (S420). Here, only the temperature is used as the variable for the simulation. Therefore, through the simulation the actual shift on the trigger point resistance of the sensing circuit can be obtained.

Next, according to the previously obtained shift, an offset resistor is disposed to the eFuse system to compensate for the shift on the trigger point resistance of the sensing circuit (S430). Through the foresaid method, an actual shift on the trigger point resistance of the sensing circuit is obtained, and an offset resistor suitable for compensating for the shift is disposed to the eFuse system. Therefore, the problem that marginal passed bit may fail can be resolved.

It is deserved to be mentioned that not only the temperature affects the value of trigger point resistance, the composition of device components in the sensing circuit and the voltage supplied to the sensing circuit may also influence the shift of trigger point resistance of the sensing circuit. Accordingly, an embodiment concerning the composition and supplied voltage of the sensing circuit is further provided below.

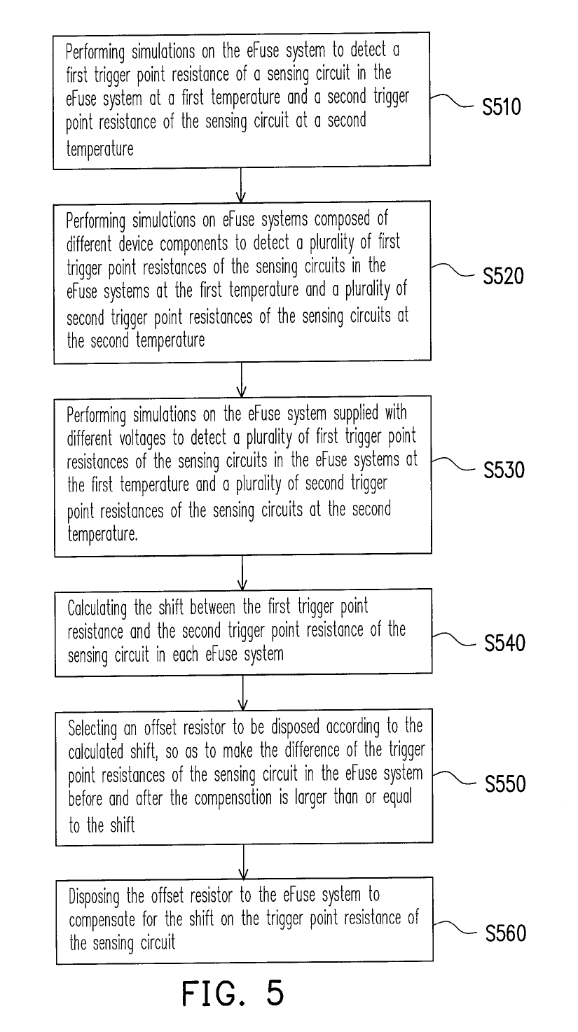

FIG. 5 is a flowchart illustrating the method for testing an eFuse system according to one embodiment of the present invention. Referring to FIG. 5, the present embodiment is applied to the aforesaid eFuse system and used for determining the resistance of the offset resistor to be disposed to the eFuse system, the detail steps for testing the eFuse system are described below.

First, simulations are performed on the eFuse system, so as to detect a first trigger point resistance of a sensing circuit in the eFuse system at a first temperature and a second trigger point resistance of the sensing circuit at a second temperature (S510).

Then, simulations are further performed on a plurality of eFuse systems which are composed of different device components, so as to detect a plurality of first trigger point resistances of the sensing circuits in the eFuse systems at the first temperature and a plurality of second trigger point resistances of the sensing circuits at the second temperature (S520).

Next, simulations are further performed on the eFuse system supplied with different voltages, so as to detect a plurality of first trigger point resistances of the sensing circuits in the eFuse systems at the first temperature and a plurality of second trigger point resistances of the sensing circuits at the second temperature (S530).

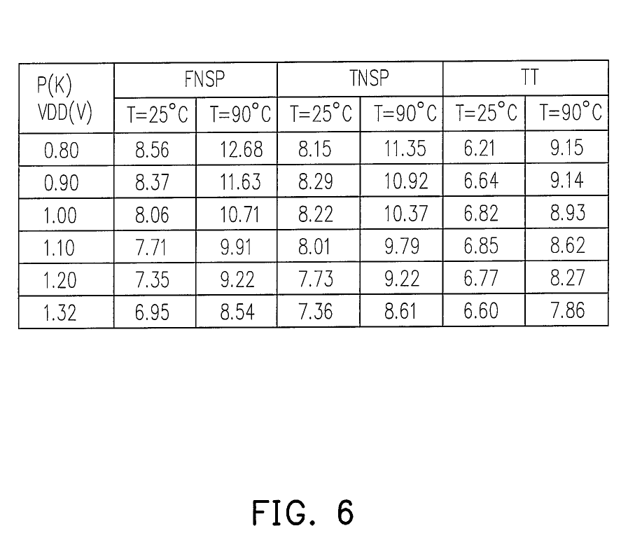

After all the simulations are finished, the detected results are used for calculating the shift between the first trigger point resistance and the second trigger point resistance of the sensing circuit in each eFuse system (S540). FIG. 6 is a table illustrating the trigger point resistance detected in the simulations according to one embodiment of the present invention. Referring to FIG. 6, the conditions of the simulations are defined by temperature (25 centigrade and 90 centigrade), device component (FNSP, TNSP, TT), and supplied voltage (0.80V, 0.90V, 1.00V, 1.10V, 1.20V, 132V). The FNSP refers to the device components containing fast NMOSs and slow PMOSs. The TNSP refers to the device components containing typical NMOSs and slow PMOSs. And the TT refers to the device components containing typical NMOSs and typical PMOSs.

According to the calculated shifts, an appropriate value of the offset resistor to be disposed is selected to make the difference of the trigger point resistances of the sensing circuit in the eFuse system before and after the compensation is greater than or equal to the shift (S550). That means value of the trigger point resistance can be raised to be greater than the highest detected value of the trigger point resistance, such that the criteria for passed bit determination is raised and the situation of marginal passed bit failure can be avoided.

Finally, the selected offset resistor is disposed to the eFuse system to compensate for the shift on the trigger point resistance of the sensing circuit (S560). Through the foresaid method, an actual shift on the trigger point resistance of the sensing circuit is obtained, and an offset resistor suitable for compensating for the shift is disposed to the eFuse system. Therefore, all the factors that may affect the trigger point resistance are compensated.

In summary, the embodiments as described above have at least the following advantages:

1. The trigger point resistance of sensing circuit is compensated by an offset resistor, such that the influence of temperature can be minimized.

2. Simulations are performed for a plurality of eFuse systems and a worst case is selected to determine the value of the offset resistor, the defects of marginal passed bit failure can be prevented.

3. The offset resistor for compensating the trigger point resistance can be designed on a separate board, which can be used accordingly to the requirement of testing, the flexibility to test the eFuse system is enhanced.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An eFuse system, comprising:
an eFuse, wherein a resistance thereof depends on whether the eFuse is blown or not;
a sensing circuit, having a trigger point resistance and coupled to a first end of the eFuse, for sensing the resistance of the eFuse, and outputting a first signal if the sensed resistance is greater than the trigger point resistance and outputting a second signal if the sensed resistance is less than the trigger point resistance; and
an offset resistor, coupled to a second end of the eFuse, for compensating a shift on the trigger point resistance of the sensing circuit due to temperature change.

2. The eFuse system according to claim 1, further comprising:
a first switch, disposed between the sensing circuit and a ground reference voltage, for enabling or disabling the sensing circuit to sense the resistance of the eFuse and output the signal accordingly.

3. The eFuse system according to claim 1, further comprising:
a power supply, for supplying a programming current; and
a second switch, disposed between the power supply and the eFuse, for connecting or disconnecting the power supply to the eFuse, and conducting the programming current to the eFuse for blowing the eFuse.

4. The eFuse system according to claim 3, further comprising:
a blowing pad, coupled to the second end of the eFuse and the second switch, for transferring the programming current to the eFuse.

5. The eFuse system according to claim 3, further comprising:
a sensing reference pad, coupled to a second end of the offset resistor; and
a testing circuit, coupled to the sensing reference pad, for supplying a testing signal to the offset resistor for testing the eFuse system.

6. The eFuse system according to claim 3, wherein the offset resistor, the sensing reference pad, and the testing circuit are integrated on a board.

7. The eFuse system according to claim 1, wherein the temperature ranges from −40 centigrade to 125 centigrade.

8. The eFuse system according to claim 1, wherein the offset resistor comprises a poly resistor or a diffuse resistor.

9. A method for testing an eFuse system, comprising:
performing simulations on the eFuse system to detect a first trigger point resistance of a sensing circuit in the eFuse system at a first temperature and a second trigger point resistance of the sensing circuit at a second temperature; and
calculating a shift between the first trigger point resistance and the second trigger point resistance; and
disposing an offset resistor to the eFuse system to compensate for the shift on the trigger point resistance of the sensing circuit.

10. The method for testing an eFuse system according to claim 9, wherein the step of performing simulations on the eFuse system further comprises:
performing simulations on a plurality of eFuse systems composed of different device components to detect a plurality of first trigger point resistances of the sensing circuits in the eFuse systems at the first temperature and a plurality of second trigger point resistances of the sensing circuits at the second temperature.

11. The method for testing an eFuse system according to claim 10, further comprising:
calculating the shift between the first trigger point resistance and the second trigger point resistance of the sensing circuit in each eFuse system; and
disposing the offset resistor to the eFuse system to compensate for the shift on the trigger point resistance of the sensing circuit in the eFuse system.

12. The method for testing an eFuse system according to claim 9, wherein the step of performing simulations on the eFuse system further comprises:
performing simulations on the eFuse system supplied with a plurality of voltages to detect a plurality of first trigger point resistances of the sensing circuits in the eFuse systems at the first temperature and a plurality of second trigger point resistances of the sensing circuits at the second temperature.

13. The method for testing an eFuse system according to claim 12, further comprising:
calculating the shift between the first trigger point resistance and the second trigger point resistance of the sensing circuit in each eFuse system; and
disposing the offset resistor to the eFuse system to compensate for the shift on the trigger point resistance of the sensing circuit in the eFuse system.

14. The method for testing an eFuse system according to claim 9, wherein the step of disposing an offset resistor to the eFuse system further comprises:
selecting the offset resistor to be disposed according to the calculated shift, so as to make the difference of the trigger point resistances of the sensing circuit in the eFuse system before and after the compensation is larger than or equal to the shift.

15. The method for testing an eFuse system according to claim 9, wherein the eFuse system is programmed at the first temperature and tested at the second temperature.

16. The method for testing an eFuse system according to claim 15, wherein the first temperature is about 25 centigrade while the second temperature is about 90 centigrade.
